(19) United States
(12) Patent Application Publication
(10) Pub. No.: US 2013/0252440 A1
(43) Pub. Date: Sep. 26, 2013

(54) PRETREATMENT AND IMPROVED DIELECTRIC COVERAGE

(71) Applicant: APPLIED MATERIALS, INC., Santa Clara, CA (US)

(72) Inventors: Lei Luo, (US); Shankar Venkataraman, San Jose, CA (US); Manuel A. Hernandez, Santa Clara, CA (US); Kedar Sapre, (US); Zhong Qiang Hua, (US)

(73) Assignee: APPLIED MATERIALS, INC., Santa Clara, CA (US)

(21) Appl. No.: 13/623,792

(22) Filed: Sep. 20, 2012

Related U.S. Application Data
(60) Provisional application No. 61/539,336, filed on Sep. 26, 2011.

(51) Int. Cl. H01L 21/02

(52) U.S. Cl. CPC H01L 21/0226
USPC 438/787

(57) ABSTRACT

Methods of conformally depositing silicon oxide layers on patterned substrates are described. The patterned substrates are plasma treated such that subsequently deposited silicon oxide layers may deposit uniformly on walls of deep closed trenches. The technique is particularly useful for through-substrate vias (TSVs) which require especially deep trenches. The trenches may be closed at the bottom and deep to enable through-substrate vias (TSVs) by later removing a portion of the backside substrate (near to the closed end of the trench). The conformal silicon oxide layer thickness on the sidewalls near the bottom of a trench is greater than or about 70% of the conformal silicon oxide layer thickness near the top of the trench in embodiments of the invention. The improved uniformity of the silicon oxide layer enables a subsequently deposited conducting plug to be thicker and offer less electrical resistance.

### CROSS-REFERENCES TO RELATED APPLICATIONS

This application claims the benefit of U.S. Provisional Application No. 61/539,336, filed Sep. 26, 2011, and titled “PRETREATMENT AND IMPROVED DIELECTRIC COVERAGE OF DEEP TRENCHES.” The entire contents of which are hereby incorporated by reference for all purposes.

### BACKGROUND OF THE INVENTION

In the field of semiconductor chip fabrication and testing, a through-substrate via provides electrical continuity between the top and bottom surfaces of a semiconducting substrate. Through-substrate vias may also be referred to as through-silicon vias, though the substrate is not required to be silicon. Also referred to as a TSV, through-substrate vias are vertical electrical connections that extend from one of the electrically conductive levels formed on the top surface of a wafer or IC die (e.g., contact level or one of the metal interconnect levels) to the backside (bottom) surface. A device which uses TSVs can be bonded face-up and utilize vertical electrical paths to couple to other IC devices. In so doing, the electrical paths are significantly shortened relative to conventional wire bonding technology, generally leading to significantly faster device operation.

A TSV is fabricated by etching deeply into the semiconducting wafer, or substrate, of the semiconductor chip. TSVs are formed to a depth (e.g., 100 to 200 μm) that is significantly less than the full wafer thickness (e.g., 300 to 800 μm) using chemical etching, laser drilling, or one of several energetic methods, such as Reactive Ion Etching (RIE). Once the vias are formed, they are generally framed with a dielectric liner to provide electrical isolation from the surrounding substrate, and then made electrically conductive by filling the vias with an electrically conductive filler material (e.g., copper, tungsten, or doped polysilicon) to form embedded TSVs. The bottom of the embedded TSV is generally referred to as an embedded TSV tip.

Since most electrically conductive filler materials are metals that can degrade minority carrier lifetimes (e.g., copper or tungsten), a barrier layer is generally deposited on the dielectric liner. In the case of an electroplated metal (e.g., copper) process, a seed layer is generally added after the barrier layer. A backgrinding step is then conventionally used to thin the wafer by removing a sufficient thickness of the substrate (e.g., 50 to 300 μm) from the bottom surface of the wafer to reach the embedded TSV tip to expose the electrically conductive filler material at the distal end of the TSV tip. At this point, the distal end of the completed TSV tip is conventionally flush with the bottom surface of the substrate. A metal connection can then be made to the various TSV tips from the bottom of the substrate.

Upon completion, the performance of the device depends, in part, on the uniformity of the dielectric liner formed in the via prior to the deposition of the metal filler. A large difference in rate of formation of the dielectric between the bottom and the top of the via results in a much thicker than necessary dielectric near the top of the TSV. This reduces the diameter of the metal via, increases the resistance of the TSVs and may therefore limit the performance the completed devices.

Therefore, it is desirable to be able to form a dielectric liner on through-substrate vias (TSVs) with high uniformity. This and other needs are addressed in the present invention.

### BRIEF SUMMARY OF THE INVENTION

Methods of conformally depositing silicon oxide layers on patterned substrates are described. The patterned substrates are plasma treated such that subsequently deposited silicon oxide layers may deposit uniformly on walls of deep closed trenches. The technique is particularly useful for through-substrate vias (TSVs) which require especially deep trenches. The trenches may be closed at the bottom and deep to enable through-substrate vias (TSVs) by later removing a portion of the backside substrate (near to the closed end of the trench). The conformal silicon oxide layer thickness on the sidewalls near the bottom of a trench is greater than or about 70% of the conformal silicon oxide layer thickness near the top of the trench in embodiments of the invention. The improved uniformity of the silicon oxide layer enables a subsequently deposited conducting plug to be thicker and offer less electrical resistance.

Embodiments of the invention include methods for forming a silicon oxide layer in a deep trench on a patterned substrate in a substrate processing region of a substrate processing chamber. The methods include the sequential steps of (1) transferring the patterned substrate into the substrate processing region; (2) flowing an inert gas into the substrate processing region while forming a treatment plasma within the substrate processing region to treat the walls of the deep trench; and (3) flowing a silicon-containing precursor and ozone into the substrate processing region to form a conformal silicon oxide layer on the deep trench. The substrate processing region is plasma-free during formation of the conformal silicon oxide layer. The deep trench has substantially vertical walls and is more than ten microns deep.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### BRIEF DESCRIPTION OF THE DRAWINGS

A further understanding of the nature and advantages of the disclosed embodiments may be realized by reference to the remaining portions of the specification and the drawings.

FIG. 1A shows an exemplary cross-sectional view of a processor die.

FIG. 1B shows another exemplary cross-sectional view of a processor die.

FIG. 2A is a flow chart of a conformal silicon oxide deposition process according to disclosed embodiments.

FIG. 2B is a cross-sectional view of a deep trench lined with conformal silicon oxide according to disclosed embodiments.

FIG. 3 shows a simplified representation of a semiconductor processing system according to embodiments of the present invention.

FIG. 4A shows a simplified representation of the user interface for a semiconductor processing system in relation to a processing chamber in a multi-chamber system.

FIG. 4B shows a simplified diagram of a gas panel and supply lines in relation to a processing chamber.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

Methods of conformally depositing silicon oxide layers on patterned substrates are described. The patterned substrates are plasma treated such that subsequently deposited silicon oxide layers may deposit uniformly on walls of deep closed trenches. The technique is particularly useful for through-substrate vias (TSVs) which require especially deep trenches. The trenches may be closed at the bottom and deep to enable through-substrate vias (TSVs) by later removing a portion of the backside substrate (near to the closed end of the trench). The conformal silicon oxide layer thickness on the sidewalls near the bottom of a trench is greater than or about 70% of the conformal silicon oxide layer thickness near the top of the trench in embodiments of the invention. The improved uniformity of the silicon oxide layer enables a subsequently deposited conducting plug to be thicker and offer less electrical resistance.

TSVs allow vertical metal interconnections through thinned silicon substrates where both ends of the interconnect are accessible for contact. The exposed ends on each side of the substrate may be contacted with conductive materials such as micro-bumps or pillars, onto which companion chips may be stacked with upwards of eight or more chips. For example, TSVs formed through memory chips can allow several of these chips to be stacked. The TSVs run through each individual die composing the completed chip to provide the vertical interconnection paths, and then each die is connected with the next in the tier with micro-bumps, for example. Some benefits of such a packaging technique are that a more compact form factor may be produced in the resultant chips. Reducing the form factor reduces the interconnect length between chips and increases the speed of the assembled devices.

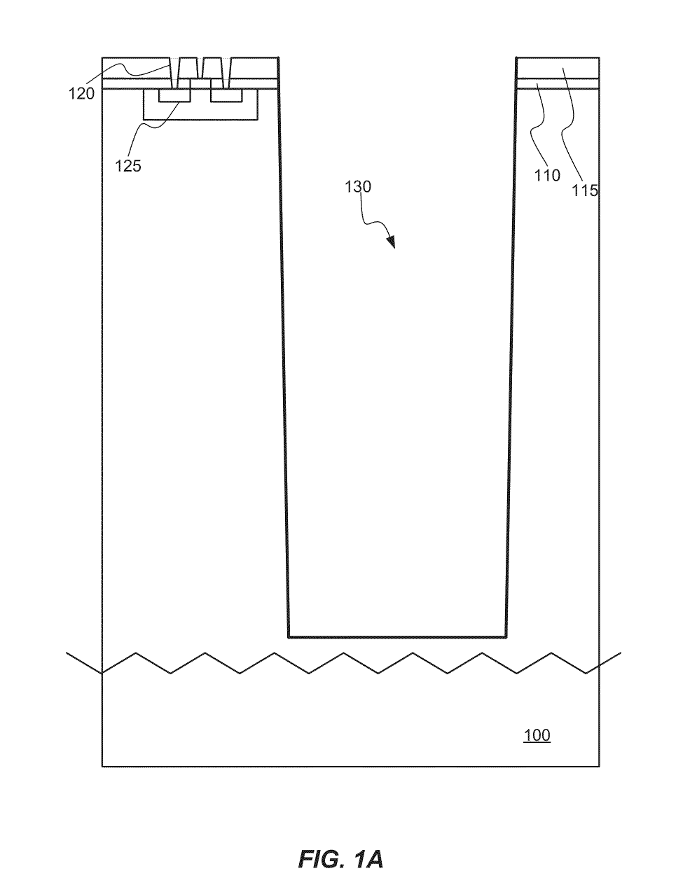

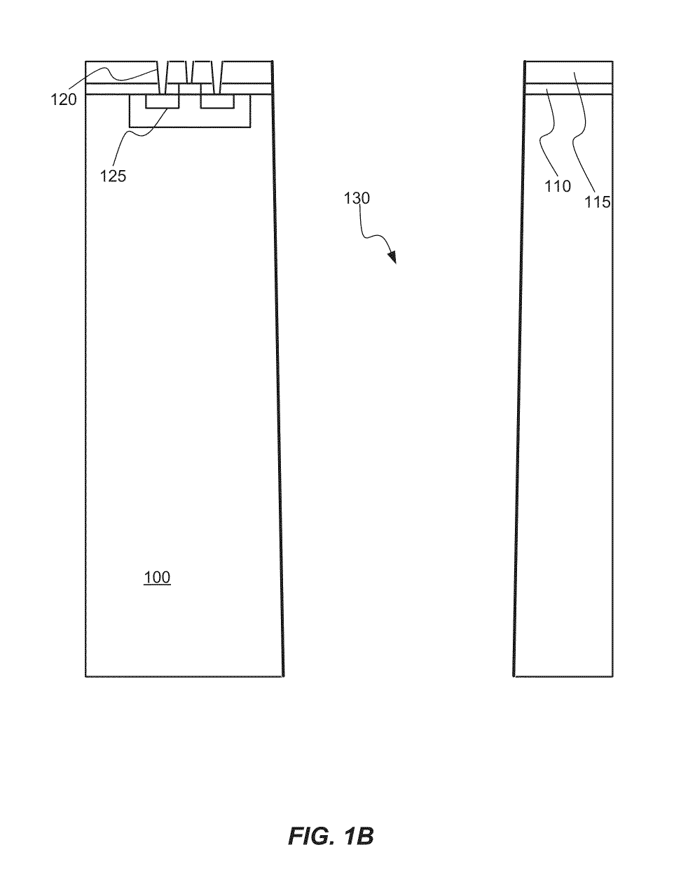

FIG. 1A shows an exemplary cross-section view of a substrate 100 on which certain features have been formed. FIG. 1A is intended to aid in understanding the differences between TSVs as compared to trenches and gaps utilized in transistor level features. FIG. 1A is not intended to limit the scope of the present technology in any way. A process has been performed on the substrate 100 similar to a via-middle approach to device manufacture in which the via is formed after transistor level processing. As shown, dielectric layers 110, 115 may be deposited prior to forming transistor features 125 and gaps (aka, trenches 120). Gaps and trenches 120 formed during transistor processing may have widths of about 10 nm or less and heights of less than or about 100 nm. After transistor level processing has been performed, a via 130 may be etched into the substrate. The via may have a width of up to 5 μm or more, and a depth of up to 50 μm or more—distances that are two orders of magnitude or more and three orders of magnitude or more, respectively, than the minimum feature size of the transistors formed on the substrate. A barrier and/or liner layer may be deposited along the walls of the via prior to seeding with copper or a conductive metal. The via may be filled with copper or some other conductive metal to provide the interconnect through the wafer. Both transistor formation and TSV formation may include many more steps, with the formation of many more trenches and vias across the device. Further manufacturing steps may be performed including BEOL contact formation, deposition of interlayer dielectrics, and formation of chip-bonding sites (not shown). Thinning of the substrate wafer may be performed as shown in FIG. 1B to expose the back-side of the TSV so that the via extends all the way through the substrate to provide a contact point for electrical connection through the substrate.

Through-substrate vias (TSVs) may be made in several ways including via first, via middle, or via last, which indicate when in the chip processing the via is made. Via first describes the formation of vias during front-end fabrication in which the vias are often formed prior to the formation of a transistor. In via middle, or interconnect TSV, the metal-filled TSVs may be added after the transistor has been finished. For via last, the vias are formed on the device side of the substrate after back-end-of-the-line (BEOL) processing, and the substrate may be bonded to a carrier wafer for the via formation. Through-substrate vias (TSVs) place unique requirements on dielectric deposition uniformity.

Embodiments of the invention are directed to methods of forming silicon oxide in deep closed trenches on a patterned surface of a substrate. A plasma treatment prior to deposition of the silicon oxide has been found to make the silicon oxide thickness near the bottom of the deep trench more similar to the silicon oxide thickness near the top. The silicon oxide is deposited after the plasma treatment by a non-plasma process (e.g. sub-atmospheric CVD or SACVD). Specifically, the silicon oxide is deposited by flowing a silicon-containing precursor and an oxidizing precursor into a processing chamber to form silicon oxide on the substrate. The silicon-containing precursor may include TEOS and the oxidizing precursor includes ozone (O₃). The inventors have hypothesized that the plasma treatment affects the sidewalls of the deep trenches to mitigate the site selectivity of the exemplary TEOS-O₃ deposition process. The plasma treatment may be producing a more even distribution of nucleation sites for the silicon oxide layer, which appears to homogenize the growth rate at varied depths along the deep closed trench.

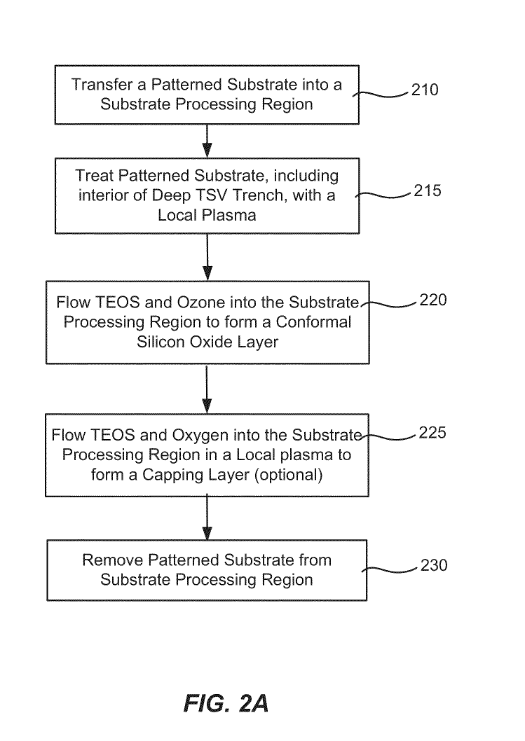

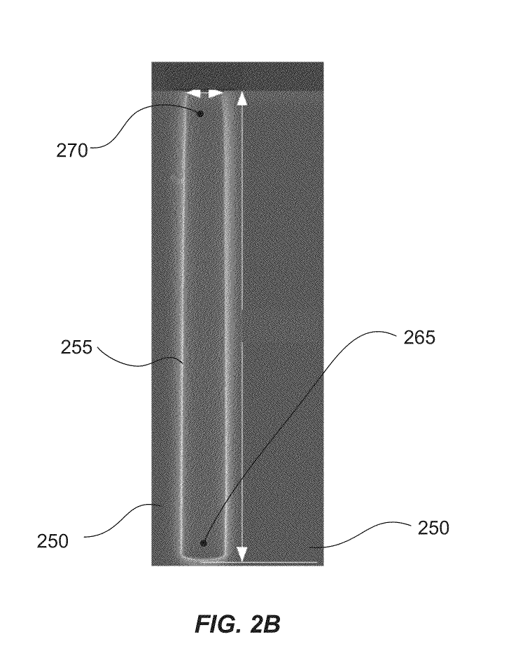

In order to better understand and appreciate the invention, reference is now made to FIG. 2A which is a flow chart of a conformal silicon oxide deposition process according to disclosed embodiments. The process begins when a patterned substrate is transferred into a processing chamber (operation 210). The patterned substrate has a deep trench which will later be filled with a conducting material to form a through substrate via (TSV). But first, the patterned substrate is treated (operation 215) by flowing an inert gas into the substrate processing region of the substrate processing chamber. A plasma is applied within the substrate processing region to excite the inert gas. After the patterned substrate is treated, a silicon-containing precursor (TEOS) and ozone are flowed into the chamber to deposit a conformal silicon oxide layer (operation 220). Following the growth of the conformal silicon oxide layer, the substrate is removed from the chamber in operation 230.

During treatment (operation 215) of the patterned substrate, the plasma power applied to the substrate processing region may oscillate in the radio frequencies (RF). A single frequency may be used to excite the plasma formed from the inert gas and the single frequency may be greater than five megahertz or less than five megahertz in disclosed embodiments. In other embodiments, two or more plasma power frequencies are used (e.g. a dual frequency plasma) to excite the plasma with one being above five megahertz and one below five megahertz. For example, a high frequency of 13.56 MHz may be combined with a low frequency of 350 kHz and the combination may be used to excite the plasma in the substrate processing region. The plasma power itself may be between 250 watts and about 1000 watts or between about 350 watts and about 650 watts. In the event that a multi-frequency plasma excitation is used, the upper frequency may be applied with a power between 200 watts and about 700 watts, between about 250 watts and about 500 watts or between about 300 watts and about 400 watts in disclosed embodiments. Meanwhile, the lower plasma frequency may be applied with a power between 50 watts and about 250 watts, between about 75 and about 200 watts or between about 100 and about 150 watts in embodiments of the invention.

The treatment (operation 215) results in little or essentially no deposition on the walls of the deep trench in disclosed embodiments. This may also hold true for the bottom of the deep trench. Essentially no deposition allows for a minute amount of deposition which does not functionally harm the subsequent deposition of the conformal silicon oxide layer or the conductivity provided by the completed through-substrate via. Any deposition may be less than or about 1 nm or less than or about 0.5 nm in embodiments of the invention. The treatment (operation 215) may also result in little or essentially no removal of material from the walls (or bottom) of the deep trench in disclosed embodiments.

The inert gas may be flowed into the substrate processing region before or during the plasma excitation. The inert gas may include one or more of helium, argon, nitrogen (N₂), neon, xenon and the like. The inert gas comprises nitrogen (N₂) and helium in embodiments of the invention. The term “inert gas” is used herein to describe any such gas which alters the surface to promote uniform deposition of silicon oxide, but does not result in significant deposition. The pressure in the substrate processing region during the treatment of the patterned substrate may be between about 0.5 torr and about 10 torr, between about 1 torr and about 8 torr, between about 2 torr and about 7 torr or between about 3 torr and about 6 torr in embodiments of the invention.

During the formation of the conformal silicon oxide layer (operation 220), the flow rate of TEOS during deposition of the conformal silicon oxide layer may be between about 0.5 grams per minute and about 10 grams per minute, between about 1 gram per minute and about 7 grams per minute or about 2-5 grams per minute in disclosed embodiments. Substantially inert carrier gases (helium, argon and/or nitrogen) may be used to assist in delivery of TEOS into the chamber. The magnitude of carrier gas flow rates is typically given in standard cubic centimeters per minute (sccms). The magnitude of the mass flow of the gas carried by the carrier gas is typically given in grams per minutes and does not include the mass flow of the carrier gas. Flow rates, as used herein, are not necessarily constant during the process. Flow rates of the different precursors may be initiated and terminated in different orders and their magnitudes may be varied. Unless otherwise indicated, mass flow rate magnitudes indicated herein are given for the approximate peak flow rate used during the process. The flow rate of ozone during deposition of the conformal silicon oxide layer may be between about 5,000 sccm and about 100,000 sccm, between about 10,000 sccm and about 70,000 sccm or between about 20,000 sccm and about 50,000 sccm. The flow rate of the ozone into the substrate processing region may be about 30,000 sccm. Flow rate magnitudes indicated herein are for deposition on one side of a single 300 mm diameter wafer (area approximately 700 cm²). Appropriate correction based on deposition area is needed for multiple wafers, larger or smaller wafers, double sided deposition or deposition on alternative geometry substrates (e.g. rectangular substrates).

Generally speaking, the silicon-containing precursor includes one or more precursors which comprise a Si—O bond. The silicon-containing precursor may include tetraethyl orthosilicate (TEOS), tetramethyl orthosilicate (TMOS), triethoxysilane (TRIES) or hexamethyl disiloxane (HMDS). These precursor each include at least one Si—O bond which enables them to form conformal silicon oxide films under a relatively wide variety of conditions, albeit with some site selectivity addressed herein.

The pressure in the substrate processing region may be about 300 torr or greater, about 500 torr or greater or about 600 torr or greater in embodiments of the invention. Higher pressures further increase the conformality of the silicon oxide layer. The substrate temperature during deposition may be below or about 600° C., below or about 540° C., below or about 500° C., below or about 400° C., below or about 350° C. or below or about 300° C. in disclosed embodiments. The substrate temperature during deposition may be above or about 100° C., above or about 150° C., above or about 200° C. or above or about 300° C. in disclosed embodiments. Each of the lower bounds may be combined with any of the upper bounds on the substrate temperature to form additional ranges on the substrate temperature according to additional disclosed embodiments. Depending on the type of via process being performed (e.g., via first or via middle or via last), the temperature of the processing chamber may be kept below a certain threshold in order to prevent damage to previously deposited materials. For example, in via middle and via last processing, transistor level production has already been performed. As a result, the temperature for subsequent processing including via formation and lining may be kept at or below about 400° C., for example, in order to prevent damage to previously deposited films.

FIG. 2B is a cross-sectional view of a deep trench lined with conformal silicon oxide according to disclosed embodiments. The deep trench is formed into a silicon substrate 250 and is lined with a conformal silicon oxide layer 255. The thickness of the conformal silicon oxide layer may be greater than or about 0.1 μm, greater than or about 0.15 μm or greater than or about 0.2 μm in disclosed embodiments. The thickness of the conformal silicon oxide layer may be less than or about 1 μm, less than or about 0.75 μm or less than or about 0.5 μm in disclosed embodiments. Each of the lower bounds may be combined with any of the upper bounds on the substrate temperature to form additional ranges on the substrate temperature according to additional disclosed embodiments. The inclusion of the treatment operation enables the thickness of conformal silicon oxide layer 255 to be more homogeneous along the depth of the trench. Measurements were made near the top of the deep trench 270 and near the bottom of the deep trench 265 and compared to measure the effectiveness of the treatment operation.

Measurements were made using a scanning electron microscope (SEM) to quantify the effect of using the plasma treatment on the thickness of the conformal silicon oxide layer. A conformal silicon oxide layer was deposited on a patterned substrate having a deep trench with and without the preceding plasma treatment. Without the plasma pre-treatment, the thickness of the silicon oxide layer near the top of the deep trench (e.g. within one micron of the top) was about 0.400 μm while a similar measurement near the bottom of the deep trench (e.g. within one micron of the bottom) was about 0.260 μm. Using the plasma pre-treatment, the thickness of the silicon oxide layer near the top of the deep trench was about 0.424 μm while a the thickness near the bottom of the deep trench was about 0.320 μm. The thickness near the bottom was about 65% of the thickness near the top without the plasma pre-treatment. With the plasma pre-treatment, the thickness near the bottom improved to about 75% of the thickness near the top. These measurements were made on a deep trench which was closed at the bottom. The trench was about fifty microns (50 μ643 m) deep and five microns wide with a circular cross-section. The plural term “walls” may be used herein to refer to both sides of a trench, despite the fact that the two walls on either side of a cross-sectional view may be part of the same wall (e.g. around the circumference of the circular cross-section). The thickness of the conformal silicon oxide layer within one micron of the bottom of the deep trench is at least 70%, 75% or 80% of the thickness near the top of the deep trench, in embodiments of the invention.

The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low horizontal aspect ratio trench (as viewed from above) which may or may not be filled with metal to form a vertical electrical connection. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

The conformal silicon oxide layer may be more conformal especially within the via than conventional techniques. For many semiconductor processes utilizing trenches, such as those formed during transistor processing, the trench formed may be less than about 1 μm in width, or diameter, and may often be less than about 50 nm, etc. or less. Through silicon vias, on the other hand, may be more than about 1 μm wide, and may alternatively have a width greater than about 2 μm, about 3 μm, about 4 μm, about 5 μm, etc., in embodiments of the invention. The vias (aka deep trenches) may be less than or about 15 μm wide, less than or about 10 μm wide, less than or about 8 μm microns wide or less than or about 5 μm microns wide in disclosed embodiments. Additionally, many trenches and gaps may be less than about 1 μm in height, and can routinely be about 100 nm or less. TSVs, on the other hand, may have heights greater than about 1 μm in height, or alternatively greater than about 5 μm, about 10 μm, about 20 μm, about 35 μm, about 50 μm, about 75 μm, 100 μm, etc., in disclosed embodiments. Because the vias are so much deeper than conventional trenches, gases utilized for liners must travel a greater distance. When these gases deposit material, the deposition may occur preferentially towards the top of the via. Accordingly, if the thickness of the liner cannot be greater than a certain amount based on the amount of conductive material required, this thickness may be reached near the top of the via prior to when an adequate deposition has occurred in regions further down the via walls. If an insufficient amount of liner material is deposited along the via, the conductive material, such as copper, may diffuse through the liner corrupting the integrity of a nearby device. A substantially conformal silicon oxide liner may be deposited along the entire length of the via. The liner may become thinner at the lower portions of a via, however, the similarity between the thickness at the bottom and the top allows a larger volume of conductive material to fill the via and therefore a lower resistance plug to be inserted.

The via formed may have a height:width aspect ratio greater than or about 5:1, and may alternatively have an aspect ratio greater than or about 10:1, greater than or about 15:1, greater than or about 20:1, greater than or about 25:1, etc., or more. The height may equivalently be referred to as the depth of the trench herein. With TSV technology, although the technical ratio of the trench height:width may be comparable with other trenches, such as isolation trenches formed during transistor processing, the actual height and width dimensions may be much greater. For example, trenches that are filled in certain gapfilling technologies may have an aspect ratio of about 10:1, where the actual height and width are 100 nanometers and 10 nanometers respectively. TSV trenches, on the other hand, may be etched through the entirety of the substrate, and although may have an aspect ratio of 10:1, this ratio may be based on actual height and width values of about 50 μm and about 5 μm respectively, for example.

The conformal silicon oxide layer may be hygroscopic and may therefore benefit from a capping layer deposited on top of the conformal silicon oxide layer prior to being exposed to atmosphere. Otherwise, water in the atmosphere will be absorbed by the hygroscopic conformal silicon oxide layer. In this case, further deposition of a silicon oxide capping layer may be included in the methods presented herein to reduce the absorption of moisture from the atmosphere outside processing chambers. A silicon oxide capping layer may be deposited on the hygroscopic conformal silicon oxide layer (operation 225) in a separate processing chamber or before the patterned substrate is removed from the substrate processing region.

The silicon oxide capping layer is deposited by flowing TEOS (or another silicon-containing precursor including a Si—O bond) and molecular oxygen (O₂) into the substrate processing region. The thickness of the silicon oxide capping layer may be greater than or about 100 nm, greater than or about 200 nm or greater than or about 300 nm in disclosed embodiments. A local plasma is used to excite the combination of precursors and form the capping silicon oxide layer on the patterned substrate. The pressure in the substrate processing region may be greater than or about 0.5 torr and less than or about 50 torr, greater than or about 1 torr and less than or about 25 torr, or greater than or about 5 torr and less than or about 15 torr. The flow rate of the silicon-containing precursor may be greater than or about 100 sccm and less than or about 5 slm, greater than or about 200 sccm and less than or about 3 slm or greater than or about 500 sccm and less than or about 2 slm in embodiments of the invention. Flow rates given herein do not include carrier gases unless otherwise indicated. The flow rate of molecular oxygen (O₂) may be greater than or about 100 sccm and less than or about 1 slm or greater than or about 200 sccm and less than or about 800 sccm in disclosed embodiments.

During deposition of the silicon oxide capping layer, a single plasma frequency may be used to excite the plasma formed from the silicon-containing precursor and the oxygen (O₂) and the single frequency may be greater than five megahertz or less than five megahertz in disclosed embodiments. In other embodiments, two or more plasma power frequencies are used to excite the plasma with one being above five megahertz and one below five megahertz. For example, a high frequency of 13.56 MHz may be combined with a low frequency of 350 kHz and the combination may be used to excite the plasma in the substrate processing region. The plasma power during deposition of the capping layer may be between 250 watts and about 1200 watts or between about 350 watts and about 700 watts. In the event that a multi-frequency plasma excitation is used, the upper frequency may be applied with a power between 200 watts and about 750 watts or between about 250 watts and about 600 watts in disclosed embodiments. Meanwhile, the lower plasma frequency may be applied with a power between 50 watts and about 300 watts or between about 100 and about 200 watts in embodiments of the invention.

Additional process parameters are described in the course of describing an exemplary substrate processing system and chamber.

### Exemplary Substrate Processing System

Deposition chambers that may implement embodiments of the present invention may include sub-atmospheric chemical vapor deposition (SACVD) chambers and more generally, deposition chambers which allow operation at relatively high pressures without necessarily applying plasma excitation. Specific examples of CVD systems that may implement embodiments of the invention include the CENTURA ULTIMA® SACVD chambers/systems, and PRODUCER® HARP, eHARP and SACVD chambers/systems, available from Applied Materials, Inc. of Santa Clara, Calif.

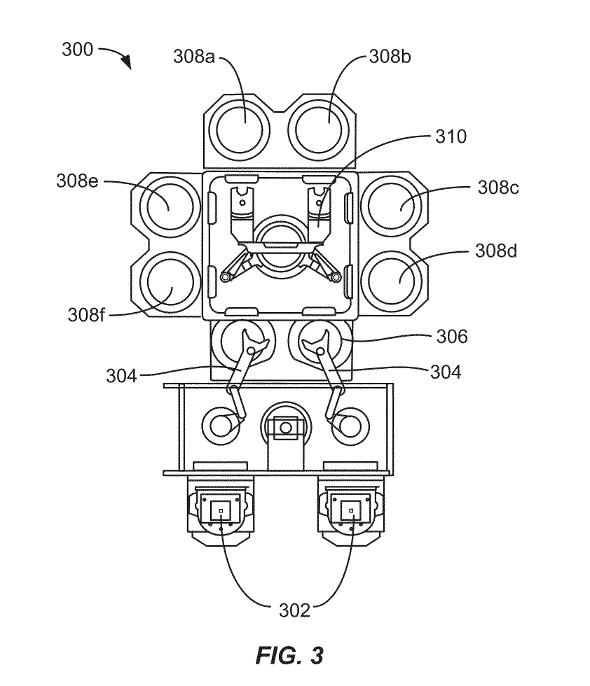

Embodiments of the deposition systems may be incorporated into larger fabrication systems for producing integrated circuit chips. FIG. 3 shows one such substrate processing system 300 of deposition, baking and curing chambers according to disclosed embodiments. In the figure, a pair of FOUPs (front opening unified pods) 302 supply substrate substrates (e.g., 300 mm diameter wafers) that are received by robotic arms 304 and placed into a low pressure holding area 306 before being placed into one of the substrate processing chambers 308a-f. A second robotic arm 310 may be used to transport the substrate wafers from the low pressure holding area 306 to substrate processing chambers 308a-f and back.

Substrate processing chambers 308a-f may include one or more system components for depositing, annealing, curing and/or etching a dielectric film on the substrate wafer. In one configuration, two pairs of the processing chamber (e.g., 308c-d and 308e-f) may be used to deposit the dielectric material on the substrate, and the third pair of processing chambers (e.g., 308a-b) may be used to treat the deposited dielectric with a plasma. In another configuration, the same two pairs of processing chambers (e.g., 308c-d and 308e-f) may be configured to both deposit and plasma treat a deposited dielectric film on the substrate, while the third pair of chambers (e.g., 308a-b) may be used for UV or E-beam curing of the deposited film. In still another configuration, all three pairs of chambers (e.g., 308a-f) may be configured to deposit and cure a dielectric film on the substrate. In yet another configuration, two pairs of processing chambers (e.g., 308c-d and 308e-f) may be used for both deposition and UV or E-beam curing of the dielectric, while a third pair of processing chambers (e.g. 308a-b) may be used for annealing the dielectric film. Any one or more of the processes described may be carried out on chamber(s) separated from the fabrication system shown in disclosed embodiments.

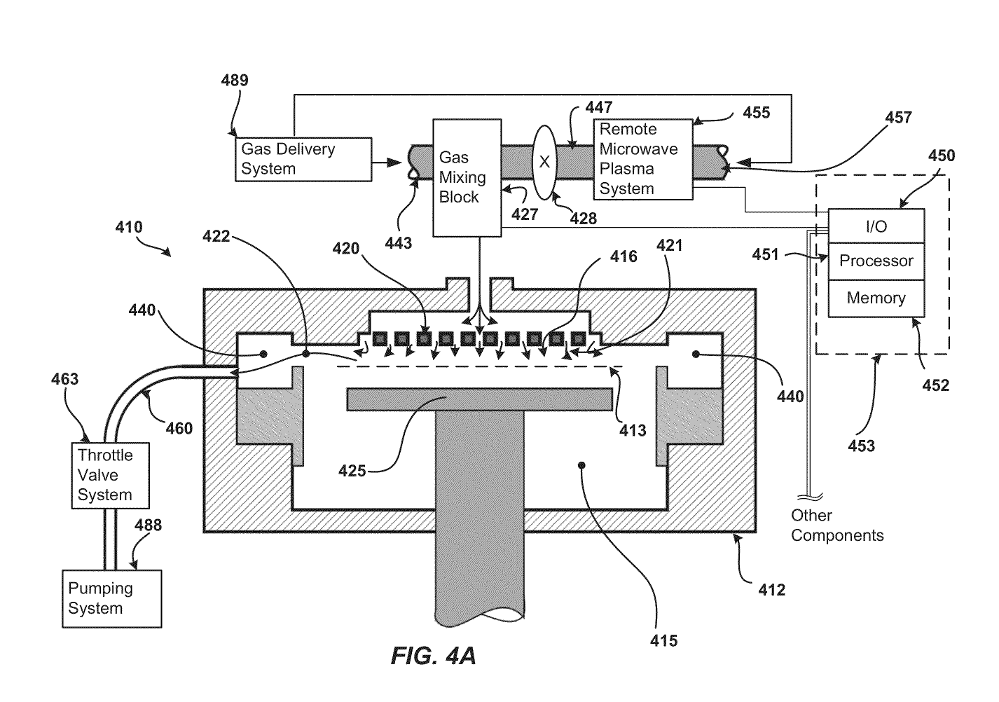

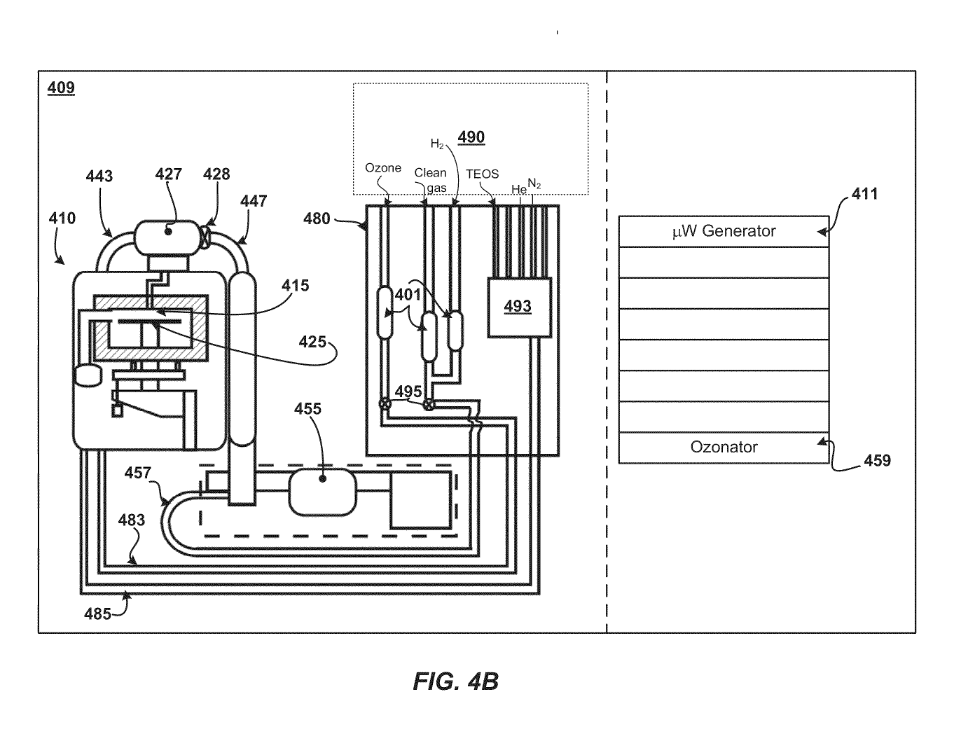

FIG. 4A shows a simplified representation of an exemplary substrate processing chamber within a substrate processing system 300. This exemplary substrate processing chamber 410 is suitable for performing a variety of semiconductor processing steps which may include CVD processes, as well as other processes, such as reflow, drive-in, cleaning, etching, and gettering processes. Multiple-step processes can also be performed on a single substrate without removing the substrate from the chamber. Representative major components of the system include a chamber interior 415 that receives process and other gases from a gas delivery system 489, pumping system 488, a remote plasma system (RPS) 455, and a system controller 453. These and other components are described below in order to understand the present invention.

Substrate processing chamber 410 includes an enclosure assembly 412 housing a chamber interior 415 with a gas reaction area 416. A gas distribution plate 420 is provided above the gas reaction area 416 for dispersing reactive gases and other gases, such as purge gases, through perforated holes in the gas distribution plate 420 to a substrate (not shown) that rests on a vertically movable heater 425 (which may also be referred to as a substrate support pedestal). Vertically movable heater 425 can be controllably moved between a lower position, where a substrate can be loaded or unloaded, for example, and a processing position closely adjacent to the gas distribution plate 420, indicated by a dashed line 413, or to other positions for other purposes, such as for an etch or cleaning process. A center board (not shown) includes sensors for providing information on the position of the substrate.

The substrate processing chamber 410 includes an enclosure assembly 412 housing a chamber interior 415 with a gas reaction area 416. A gas distribution plate 420 is provided above the gas reaction area 416 for dispersing reactive gases and other gases, such as purge gases, through perforated holes in the gas distribution plate 420 to a substrate (not shown) that rests on a vertically movable heater 425 (which may also be referred to as a substrate support pedestal). The vertically movable heater 425 can be controllably moved between a lower position, where a substrate can be loaded or unloaded, for example, and a processing position closely adjacent to the gas distribution plate 420, indicated by a dashed line 413, or to other positions for other purposes, such as for an etch or cleaning process. A center board (not shown) includes sensors for providing information on the position of the substrate.

Gas distribution plate 420 may be of the variety described in U.S. Pat. No. 6,793,733. These plates improve the uniformity of gas disbursement at the substrate and are particularly advantageous in deposition processes that vary gas concentration ratios. In some examples, the plates work in combination with the vertically movable heater 425 (or movable substrate support pedestal) such that deposition gases are released farther from the substrate when the ratio is heavily skewed in one direction (e.g., when the concentration of a silicon-containing gas is small compared to the concentration of an oxidizer-containing gas) and are released closer to the substrate as the concentration changes (e.g., when the concentration of silicon-containing gas in the mixture is higher). In other examples, the orifices of the gas distribution plate are designed to provide more uniform mixing of the gases.

Vertically movable heater 425 includes an electrically resistive heating element (not shown) enclosed in a ceramic. The ceramic protects the heating element from potentially corrosive chamber environments and allows the heater to attain temperatures up to about 800° C. In an exemplary embodiment, all surfaces of vertically movable heater 425 exposed within the chamber interior 415 are made of a ceramic material, such as aluminum oxide (Al₂O₃ or alumina) or aluminum nitride.

Reactive and carrier gases are supplied through the process gas supply line 443 into a gas mixing box (also called a gas mixing block) 427, where they are preferably mixed together and delivered to the gas distribution plate 420. The gas mixing block 427 is preferably a dual input mixing block coupled to a process gas supply line 443 and to a cleaning/etch gas conduit 447. A gate valve 428 operates to admit or seal gas or plasma from the gas conduit 447 to the gas mixing block 427. The gas conduit 447 receives gases from an RPS 455, which has an input line 457 for receiving input gases. During deposition processing, gas supplied to the gas distribution plate 420 is vented toward the substrate surface (as indicated by arrows 421), where it may be uniformly distributed radially across the substrate surface, typically in a laminar flow.

Purging gas may be delivered into the chamber interior 415 through the gas distribution plate 420 and/or an inlet port or tube (not shown) through a wall (preferably the bottom) of enclosure assembly 412. The purging gas flows upward from the inlet port past the vertically movable heater 425 and to an annular pumping channel 440. An exhaust system then exhausts the gas (as indicated by arrow 422) into the annular pumping channel 440 and through an exhaust line 460 to a pumping system 488, which includes one or more vacuum pumps. Exhaust gases and entrained particles are drawn from the annular pumping channel 440 through the exhaust line 460 at a rate controlled by a throttle valve system 463.

Vertically movable heater 425 and gas distribution plate 420 are equipped with embedded conductors used to apply plasma power to the substrate processing region to form a local plasma during the treatment of the walls of the deep trench. Plasma is not applied during deposition to increase the step coverage (make the silicon oxide layer more conformal). The substrate processing region may be described during the deposition as “plasma-free” during the growth of the conformal silicon oxide layer. “Plasma-free” does not necessarily mean the region is devoid of plasma. A low intensity plasma may be created in the substrate processing region by cosmic rays or local optical radiation, for example. These and other minor excitations would not compromise the ability to deposit conformal silicon oxide on the patterned substrate. All causes for a plasma having much lower intensity ion density than the local plasmas used during the other steps described herein do not deviate from the scope of “plasma-free”.

The RPS 455 can produce a plasma for selected applications, such as chamber cleaning or etching native oxide or residue from a process substrate. Plasma species produced in the remote plasma system (RPS 455) from precursors supplied via the input line 457 are sent via the gas conduit 447 for dispersion through the gas distribution plate 420 to the gas reaction area 416. Precursor gases for a cleaning application may include fluorine, chlorine, and other reactive elements. The RPS 455 also may be adapted to deposit plasma enhanced CVD films by selecting appropriate deposition precursor gases for use in the RPS 455.

The system controller 453 controls activities and operating parameters of the deposition system. The processor 451 executes system control software, such as a computer program stored in a memory 452 coupled to the processor 451. The memory 452 typically consists of a combination of static random access memories (cache), dynamic random access memories (DRAM) and hard disk drives but of course the memory 452 may also consist of other kinds of memory, such as solid-state memory devices. In addition to these memory means the semiconductor processing tool 409 in a preferred embodiment includes a floppy disk drive, USB ports and a card rack (not shown).

The processor 451 operates according to system control software programmed to operate the device according to the methods disclosed herein. For example, sets of instructions may dictate the timing, mixture of gases, chamber pressure, chamber temperature, plasma power levels, susceptor position, and other parameters of a particular process. The instructions are conveyed to the appropriate hardware preferably through direct cabling carrying analog or digital signals conveying signals originating from an input-output I/O module 450. Other computer programs such as those stored on other memory including, for example, a USB thumb drive, a floppy disk or another computer program product inserted in a disk drive or other appropriate drive, may also be used to operate the processor 451 to configure the semiconductor processing tool 409 for varied uses.

The processor 451 may have a card rack (not shown) that contains a single-board computer, analog and digital input/output boards, interface boards and stepper motor controller boards. Various parts of the semiconductor processing tool 409 conform to the Versa Modular European (VME) standard which defines board, card cage, and connector dimensions and types. The VME standard also defines the bus structure having a 16-bit data bus and 24-bit address bus.

The embodiment disclosed herein relies on direct cabling and a single processor 451. Alternative embodiments comprising multi-core processors, multiple processors under distributed control and wireless communication between the system controller and controlled objects are also possible.

A process for depositing a conformal silicon oxide on a patterned substrate or a process for cleaning a chamber can be implemented using a computer program product that is executed by the system controller. The computer program code can be written in any conventional computer readable programming language: for example, assembly language, C, C++, C#, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

FIG. 4B illustrates a general overview of an embodiment of the substrate processing chamber 410 in relation to a gas supply panel 480 located in a clean room. As discussed above, the semiconductor processing tool 409 includes a substrate processing chamber 410 with a vertically movable heater 425, a gas mixing block 427 with inputs from an process gas supply line 443 and a gas conduit 447, and RPS 455 with input line 457. As mentioned above, the gas mixing block 427 is configured for mixing and injecting deposition gas(es) and cleaning gas(es) or other gas(es) through the process gas supply line 443 and the input line 457 to the chamber interior 415.

The RPS 455 is integrally located and mounted below the substrate processing chamber 410 with the gas conduit 447 coming up alongside the substrate processing chamber 410 to the gate valve 428 and the gas mixing block 427, located above the substrate processing chamber 410. Plasma power generator 411 and ozonator 459 are located remote from the clean room. Gas supply lines 483 and 485 from the gas supply panel 480 provide reactive gases to the process gas supply line 443. The gas supply panel 480 includes lines from gas or liquid sources 490 that provide the process gases for the selected application. The gas supply panel 480 has a gas mixing system 493 that mixes selected gases before flow to the gas mixing block 427. Vapor from the liquids is usually combined with a carrier gas, such as helium. Supply lines for the process gases may include (i) shut-off valves 495 that can be used to automatically or manually shut off the flow of process gas into gas supply line 485 or input line 457, and (ii) liquid flow meters (LFM) 401 or other types of controllers that measure the flow of gas or liquid through the supply lines.

As an example, a mixture including TEOS as a silicon source may be used with gas mixing system 493 in a deposition process for forming a silicon oxide film. Precursors delivered to gas mixing system 493 may be liquid at room temperature and pressure and may be vaporized by conventional boiler-type or bubbler-type hot boxes. Alternatively, a liquid injection system may be used and offers greater control of the volume of reactant liquid introduced into the gas mixing system. The liquid is typically injected as a fine spray or mist into the carrier gas flow before being delivered to a heated gas supply line 485 to the gas mixing block and chamber. Of course, it is recognized that other sources of dopants, silicon, oxygen and additive precursors may also be used. Though shown as an individual line, gas supply line 485 may actually comprise multiple lines separated to discourage inter-precursor reactions before the precursors are flowed into chamber interior 415. One or more sources, such as oxygen (O₂), ozone (O₃) and/or oxygen radicals (O) flow to the chamber through gas supply line 483, to be combined with the reactant gases from heated gas supply line 485 near or in the chamber.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. A gas in an “excited state” describes a gas wherein at least some of the gas molecules are in vibrationally-excited, dissociated and/or ionized states. A gas may be a combination of two or more gases. The term trench is used throughout with no implication that the etched geometry necessarily has a large horizontal aspect ratio. Viewed from above the surface, trenches may appear circular, oval, polygonal, rectangular, or a variety of other shapes.

Having disclosed several embodiments, it will be recognized by those of skill in the art that various modifications, alternative constructions, and equivalents may be used without departing from the spirit of the disclosed embodiments. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method for forming a silicon oxide layer in a deep trench on a patterned substrate in a substrate processing region of a substrate processing chamber comprising sequential steps of:
(1) transferring the patterned substrate into the substrate processing region;
(2) flowing an inert gas into the substrate processing region while forming a treatment plasma within the substrate processing region to treat the walls of the deep trench; and
(3) flowing a silicon-containing precursor and ozone into the substrate processing region to form a conformal silicon oxide layer on the deep trench, wherein the substrate processing region is plasma-free during formation of the conformal silicon oxide layer, wherein the deep trench has substantially vertical walls and is more than ten microns deep.

2. The method of claim 1 further comprising additional steps of (4) flowing a silicon-containing precursor and molecular oxygen (O₂) into the substrate processing region to form a capping silicon oxide layer over the conformal silicon oxide layer; and (5) removing the patterned substrate from the substrate processing region.

3. The method of claim 1 wherein a thickness of the conformal silicon oxide layer within one micron of the bottom of the deep trench is at least 70% of a thickness of the conformal silicon oxide layer within one micron of the top of the deep trench.

4. The method of claim 1 wherein a thickness of the conformal silicon oxide layer within one micron of the bottom of the deep trench is at least 75% of a thickness of the conformal silicon oxide layer within one micron of the top of the deep trench.

5. The method of claim 1 wherein a thickness of the conformal silicon oxide layer within one micron of the bottom of the deep trench is at least 80% of a thickness of the conformal silicon oxide layer within one micron of the top of the deep trench.

6. The method of claim 1 wherein the walls comprise silicon.

7. The method of claim 1 wherein the silicon-containing precursor comprises tetraethyl orthosilicate (TEOS), tetramethyl orthosilicate (TMOS), triethoxysilane (TRIES), or hexamethyl disiloxane (HMDS).

8. The method of claim 1 wherein a pressure in the substrate processing region is greater than 300 torr during formation of the silicon oxide layer.

9. The method of claim 1 wherein a pressure in the substrate processing region is greater than 500 torr during formation of the silicon oxide layer.

10. The method of claim 1 wherein a pressure in the substrate processing region is greater than 600 torr during formation of the silicon oxide layer.

11. The method of claim 1 wherein the deep trench has a height:width aspect ratio of greater than or about 5:1.

12. The method of claim 1 wherein the deep trench is more than or about twenty microns deep.

13. The method of claim 1 wherein the deep trench is more than or about thirty microns deep.

14. The method of claim 1 wherein the deep trench is less than or about fifteen microns wide.

15. The method of claim 1 wherein the deep trench is less than or about eight microns wide.

16. The method of claim 1 wherein the method further comprises maintaining a temperature of the patterned substrate at about 600° C. or less during formation of the silicon oxide layer.

17. The method of claim 16, wherein the method further comprises maintaining a temperature of the patterned substrate at about 300° C. or below during formation of the silicon oxide layer.

18. The method of claim 1 wherein the deep trench is less than five microns wide.

19. The method of claim 1 wherein the treatment plasma is a dual frequency plasma.

20. The method of claim 1 wherein the silicon-containing precursor comprises an Si—O bond.
